(19) United States
(12) Patent Application Publication
(10) Pub. No.: US 2004/0223369 A1
(43) Pub. Date: Nov. 11, 2004

(54) Column decoder circuit and method for connecting data lines with bit lines in a semiconductor memory device

(75) Inventors: Byung-Gil Choi, Yongin-si (KR); Choong-Keun Kwak, Suwon-si (KR)

Correspondence Address: Frank Chau, Esq., F. CHAU & ASSOCIATES, LLC, 1900 Hempstead Turnpike, Suite 501, East Meadow, NY, 11554, US

(73) Assignee: SAMSUNG ELECTRONICS CO., LTD

(21) Appl. No.: 10/874,011

(22) Filed: Jun. 22, 2004

(30) Foreign Application Priority Data
May 7, 2003 (KR) 2003-45512

(51) Int. Cl. G11C 11/00

(52) U.S. Cl. 365/154

(57) ABSTRACT

A local column decoder circuit for electrically connecting data lines with bit lines in a semiconductor memory device, reducing a speed delay in reading and writing data and reducing the size of the semiconductor memory device. The local column decoder circuit includes a plurality of gate circuits for combining a first decoding signal for selecting a bit line with a second decoding signal for selecting a column group, and outputting a switching control signal for selecting a bit line of a corresponding column group; and a plurality of bit line selectors each for connecting the bit line of a corresponding column group among numerous column groups with a corresponding data line among numerous data lines in response to the switching control signal outputted from the plurality of gate circuits.

### TECHNICAL FIELD

The present invention relates to a semiconductor memory device, and more particularly, to a local column decoder circuit for electrically connecting data lines with bit lines for a reading or writing operation in a semiconductor memory device.

### BACKGROUND

A semiconductor memory device typically consists of numerous word lines, bit lines, a memory cell array including numerous memory cells, and a unit for designating a memory cell in the memory cell array for writing or reading necessary information. In order to input or output data to/from a given memory cell in the semiconductor memory device, a row address and a column address should be inputted and decoded to designate the given memory cell. When a memory cell is designated in a reading operation, data stored in the designated memory cell undergoes a charge sharing operation through a bit line and an amplification operation in a sense amplifier. The data amplified in the sense amplifier is then transferred to a data line through a local column decoder. Subsequently, the data transferred to the data line is outputted to an exterior terminal of the semiconductor memory device through related output circuits. In this process, an operation of reading one data bit stored in a designated memory cell is completed. It should be noted that whether the local column decoder is active is decided by a global column decoder. The global column decoder receives and decodes a column address, thereby selecting a local column decoder using the column address decoded. Thereafter, the selected local column decoder is active. The aforementioned predecoding operation executed in a global column decoder is widely known in the related fields and used by most memory devices. In a broad sense, the column decoding operation involves both the global column decoder and the local column decoder.

FIG. 1 is a block diagram of a conventional semiconductor memory device. The memory device of FIG. 1 includes an address buffer 10, a row decoder 12, a global column decoder 14, a memory cell array 16, a local column decoder 18, a data input buffer 20, a write driver 22, a data output buffer 24, and a sense amp 26.

Referring to FIG. 1, the address buffer 10 receives, buffers and outputs an address inputted from an external terminal. The row decoder 12 receives the address buffered and outputted from the address buffer 10, and decodes it and outputs a word line selection signal. The global column decoder 14 receives the address buffered and outputted from the address buffer 10, and decodes it and outputs a decoding signal for selecting a bit line and a decoding signal for selecting a column group. The local column decoder 18 receives the decoding signal for selecting a bit line and the decoding signal for selecting a column group, which are both outputted from the global column decoder 14, and then decodes both signals to connect a bit line of a corresponding column group with a data line. The memory cell array 16 writes or reads data by using the word line selection signal outputted from the row decoder 12 and a bit line selection signal outputted from the local column decoder 18. The data input buffer 20 buffers and outputs data inputted from an external terminal. The write driver 22 loads the data buffered and outputted from the data input buffer 20 in the data line. The sense amplifier 26 senses, amplifies and outputs the data outputted through the data line of the local column decoder 18. The data output buffer 24 buffers and outputs the data sensed, amplified and outputted from the sense amplifier 26 to the external terminal.

FIG. 2 is a circuit diagram illustrating in detail a conventional local column decoder.

As shown in FIG. 2, the conventional local column decoder consists of a plurality of data lines DL1˜DL4, and a first through nth column group of data connection parts 101˜10n for connecting a bit line for a corresponding column group with a corresponding data line among the plurality of data lines DL1˜DL4 in response to decoding signals YA0˜YA15 for selecting bit lines (hereinafter bit line selection signals YA0˜YA15), and decoding signals YB1˜YBn for selecting column groups (hereinafter column group selection signals YB1˜YBn), wherein both the bit line selection signals and the column group selection signals are outputted from the global column decoder 14.

The first through nth column group data connection parts 101˜10n are each composed of bit line selectors 201˜20n that each consists of 16 NMOS transistors M1˜M16. Further, each of the bit line selectors 201˜20n selects a corresponding bit line in response to one of the bit line selection signals YA0˜YA15 outputted from the global column decoder 14 to select a bit line; and a plurality of NMOS transistors M21˜M2n each of which is connected to the bit line selectors 201˜20n and is connected to a bit line of a corresponding column group with a corresponding data line in response to one of the column group selection signals YB1˜YBn outputted from the global column decoder 14 to select a column group.

In a conventional memory read or write operation, the global column decoder 14 receives and decodes an address buffered and outputted from the address buffer 10, and outputs one of the bit line selection signals YA0˜YA15 for selecting a bit line and one of the column group selection signals YB1˜YBn for selecting a column group. The outputted bit line selection signals YA0˜YA15 are applied to the gates of the sixteen NMOS transistors M1˜M16, and the sixteen NMOS transistors M1˜M16 each outputs data to one bit line among sixteen bit lines BL0˜BL15. The column group selection signals YB1˜YBn are each applied to a corresponding gate of the plurality of NMOS transistors M21˜M2n, each of which connects a bit line to a corresponding data line. For example, if the bit line selection signals YA0˜YA15 and the column group selection signals YB1˜YBn are both the signals for selecting a first column group data connection part 101, then when both are transmitted to the local column decoder 18, one transistor among sixteen NMOS transistors M1˜M16 is turned on and simultaneously an NMOS transistor M21 is turned on, thereby connecting one of the sixteen bit lines BL0˜BL15 in the first column group data connection part 101 with a data line DL1. The numerous column group data connection parts 101˜10n each becomes one column group when an NMOS transistor M2n is turned on.

However, in a read or write operation performed in the conventional local column decoder circuit described above, the NMOS transistors M21˜M2n are connected with one another in series. Therefore, when one of the NMOS transistors M21˜M2n and one of the sixteen NMOS transistors M1˜M16 are turned on to connect a bit line BLn with a data line DLn, there is a speed delay effect in the read and write operation caused by the NMOS transistors M21˜M2n connected in series. Further, for the purpose of connecting a data line DLn with a bit line BLn in one column group data connection part 101, seventeen lines are needed. Thus, the size of a semiconductor memory device increases as the size of the local column decoder consisting of the seventeen lines increases. A need therefore exists for a semiconductor memory device that has reduced speed delay in a read or write operation and also has a minimal circuit size.

### SUMMARY OF THE INVENTION

A preferred embodiment of the present invention provides a local column decoder circuit capable of reducing a speed delay in a read and write operation while also simplifying a layout of a local column decoder in a semiconductor memory device, thereby reducing the size of the semiconductor memory device.

One embodiment of the present invention provides a local column decoder, comprising: a plurality of gate circuits for combining a first decoding signal for selecting a bit line with a second decoding signal for selecting a column group, and outputting a switching control signal for selecting a bit line of a corresponding column group; and a plurality of bit line selectors for connecting the bit line of a corresponding column group among numerous column groups with a corresponding data line among numerous data lines in response to the switching control signal outputted from the plurality of gate circuits.

Further, the plurality of gate circuits each includes of four NOR gates.

In each of the bit line selectors, sixteen NMOS transistors each connected to sixteen bit lines are classified into four sub-column groups, and the four sub-column groups are each sequentially coupled with each of four data lines.

### BRIEF DESCRIPTION OF THE DRAWINGS

The above features of the present invention will become more apparent from the following description of the exemplary embodiments in conjunction with the accompanying drawings, in which:

FIG. 1 is a block diagram of a conventional semiconductor memory device;

FIG. 2 is a circuit diagram showing in detail a conventional local column decoder; and

FIG. 3 is a circuit diagram showing in detail a local column decoder according to an exemplary embodiment of the present invention.

### DETAILED DESCRIPTION OF PREFERRED EMBODIMENTS

Hereinafter, an exemplary embodiment of the present invention will be described in detail with reference to the accompanying drawings. The exemplary embodiment is provided so that this disclosure will be thorough and complete, and will fully convey concepts of the invention to one of ordinary skill in the art. However, one of ordinary skill in the art could readily envision other embodiments of the invention and nothing herein should be construed as limiting the scope of the invention.

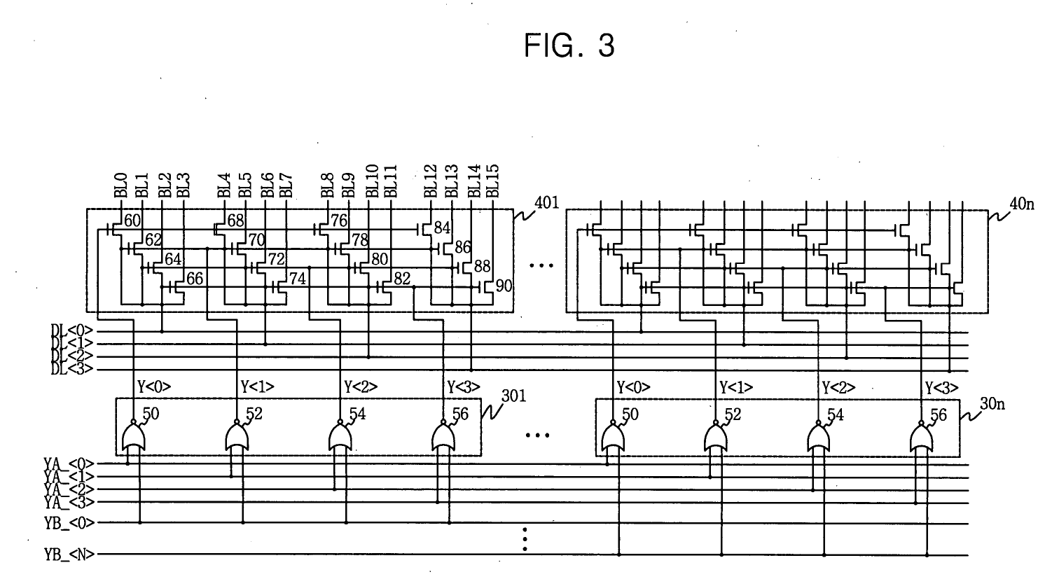

FIG. 3 is a circuit diagram showing in detail a local column decoder according to an exemplary embodiment of the present invention.

In FIG. 3, the local column decoder includes a plurality of data lines DL0˜DL3; a plurality of gate circuits 301˜30n, which each includes four NOR gates 50, 52, 54, and 56, and which each outputs a switching control signal for selecting a bit line of a corresponding column group in response to one of decoding signals YA0˜YA3 for selecting bit lines (hereinafter, bit line selection signals YA0˜YA3) and one of decoding signals YB0˜YBN for selecting column groups (hereinafter, column group selection signals YB0˜YBN), wherein both the bit line selection signals YA0˜YA3 and column group selection signals YB0˜YBN are outputted from a global column decoder 14; a plurality of bit line selectors 401˜40n for connecting a bit line with a corresponding column group among numerous column groups with a corresponding data line in response to the switching control signals outputted from the plurality of gate circuits 301˜30n; and a plurality of NMOS transistors 60˜90, each having one terminal connected to a bit line BLn and another terminal connected to a data line DLn, and yet another terminal connected to each of the four NOR gates 50, 52, 54 and 56.

In the NOR gate 50, the decoding signal YAO for selecting a bit line and the decoding signal YB0 for selecting a column group, which are both outputted from the global column decoder 14, are each connected to an input terminal of the NOR gate 50, and an output terminal of the NOR gate 50 is connected to the gates of the NMOS transistors 60, 68, 76, and 84.

In the NOR gate 52, the decoding signal YA1 for selecting a bit line and the decoding signal YB0 for selecting a column group, which are both outputted from the global column decoder 14, are each connected to an input terminal of the NOR gate 52, and the output terminal of the NOR 52 is connected to the gates of the NMOS transistors 62, 70, 78, and 86.

In the NOR gate 54, the decoding signal YA2 for selecting a bit line and the decoding signal YB0 for selecting a column group, which are both outputted from the global column decoder 14, are each connected to an input terminal of the NOR gate 54, and the output terminal of the NOR gate 54 is connected to the gates of the NMOS transistors 64, 72, 80, and 88.

In the NOR gate 56, the decoding signal YA3 for selecting a bit line and the decoding signal YB0 for selecting a column group, which are both outputted from the global column decoder 14, are each connected to an input terminal of the NOR gate 56, and the output terminal of the NOR gate 56 is connected to the gates of the NMOS transistors 66, 74, 82, and 90.

The NMOS transistors 60, 62, 64, and 66 are connected to a data line DL0, and the NMOS transistors 68, 70, 72, and 74 are connected to a data line DL1. The NMOS transistors 76, 78, 80, and 82 are connected to a data line DL2, and the NMOS transistors 84, 86, 88, and 90 are connected to a data line DL3.

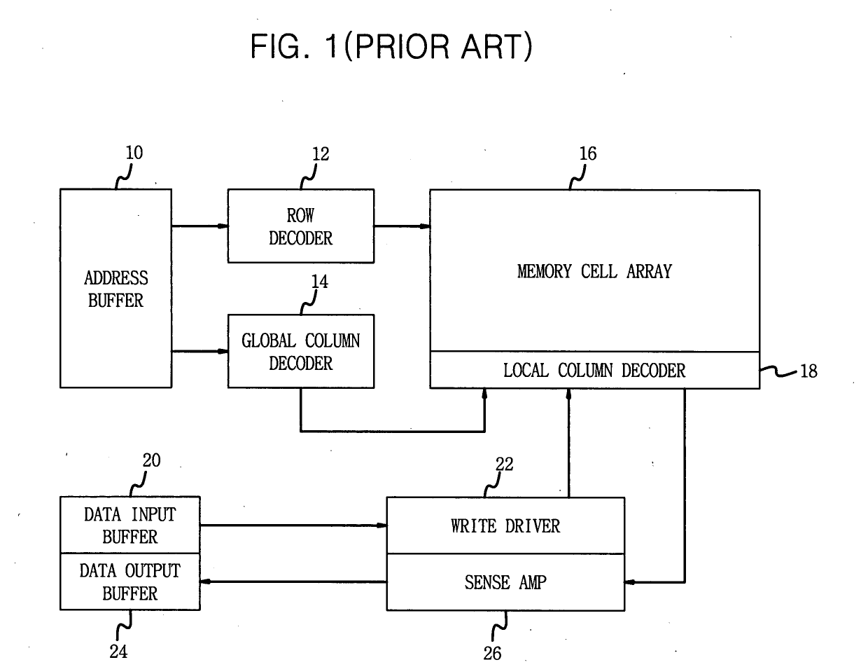

With reference to FIGS. 1 and 3, an exemplary embodiment of the present invention will be described in detail as follows.

The exemplary embodiment of the present invention will be described under an assumption that there are eight bit line selectors 401˜40n, wherein each has sixteen bit lines BL0˜BL15. Assume also that the bit line selector 401 is a main column group selector. A bit line selector 401, 402 or 40n of sixteen NMOS transistors 60-90 is shown in FIG. 3. The sixteen NMOS transistors 60-90 are classified into four sub-column groups. Four NMOS transistors 60, 62, 64, and 66 are commonly connected to the data line DL0; four NMOS transistors 68, 70, 72, and 74 are commonly connected to the data line DL1; four NMOS transistors 76, 78, 80, and 82 are commonly connected to the data line DL2; and four NMOS transistors 84, 86, 88, and 90 are commonly connected to the data line DL3.

The operation of the global column decoder 14 will be explained with reference to the global column decoder 14 referred to in FIG. 1. The global column decoder 14 receives an address buffered and outputted from an address buffer (same as address buffer 10 in FIG. 1), decodes it, and outputs one of the bit line selection signals YA0˜YA3 for selecting a bit line and one of the column group selection signals YB˜YBN for selecting a column group among a plurality of column groups. The outputted bit line selection signals YA0˜YA3 are each applied to one input terminal of the four NOR gates 50, 52, 54, and 56, and the outputted column group selection signals YB0˜YBN are each applied to each of the other input terminals of the four NOR gates 50, 52, 54, and 56. Then, the output terminals of the four NOR gates 50, 52, 54, and 56 each applies one of the switching control signals Y0˜Y3 for selecting a bit line to one of the gates of the sixteen NMOS transistors 60˜90 in the four sub-column groups. Among the sixteen NMOS transistors 60-90, transistors 60, 62, 64 and 66 connect one of the four bit lines BL0˜BL3 with the data line DL0 in response to the switching control signal Y0 for selecting a bit line; transistors 68, 70, 72 and 74 connect one of the four bit lines BL4˜BL7 with the data line DL1 in response to the switching control signal Y1 for selecting a bit line; transistors 76, 78, 80 and 82 connect one of the four bit lines BL8˜BL11 with the data line DL2 in response to the switching control signal Y2 for selecting a bit line; and transistors 84, 86, 88 and 90 connect one of the four bit lines BL12˜BL15 with the data line DL3 in response to the switching signal Y3. Therefore, all the data lines DL0˜DL3 are enabled even though a switching signal, which is an enable signal for only one output signal of the NOR gates 50, 52, 54, and 56, is outputted.

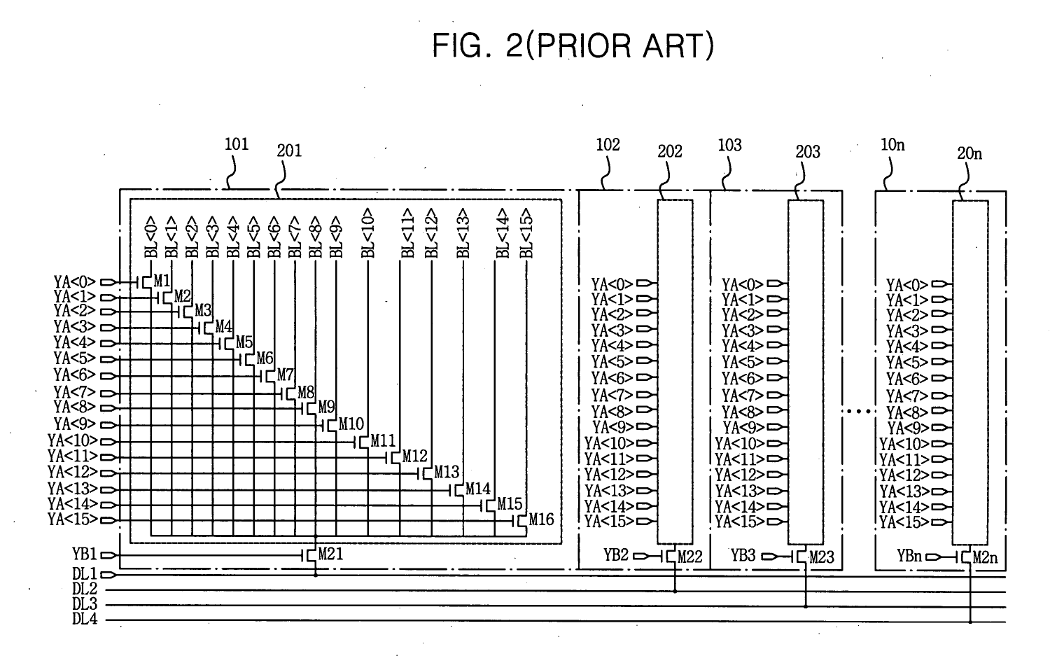

As described in FIG. 2, in a conventional read or write operation, to select sixteen bit lines of respective column groups, all seventeen lines obtained by connecting the bit line selection signals YA0˜YA15 and a column group selection signal YBn outputted from the global column decoder 14, are used.

However, according to the exemplary embodiment of the present invention described in FIG. 3, to select sixteen bit lines of respective column groups, only five lines obtained by connecting four bit line selection signals YA0˜YA3 and one column group selection signal YBN outputted from the global column decoder 14 are used. In addition, four lines outputted through the NOR gates 50, 52, 54, and 56 are used simultaneously together, and in total only nine lines are used. Therefore, the size of a semiconductor memory device is reduced since the layout of the semiconductor memory device is simplified by the reduced number of lines transmitting control signals in a local column decoder.

Further, in a conventional semiconductor memory device as described in FIG. 2, the data lines DL1˜DL4 are not directly connected to the bit lines BL0˜BL15. Instead, each of the data lines DL1˜DL4 is connected to an NMOS transistor that is commonly and serially connected to the sixteen NMOS transistors M1˜M16 that are connected with each other in series for selecting sixteen bit lines (For example, DL1 is connected to M21 that is commonly and serially connected to NMOS transistors M1˜M16). In a read or write operation, when a NMOS transistor (e.g., M21) is switched on in response to a bit line selection signal and a column group selection signal simultaneously when one of the sixteen NMOS transistors M1˜M16 is turned on, thereby connecting one of the sixteen bit lines BL0˜BL15 in the first column group data connection part 101 with a data line DL1. The NMOS transistor M21 repeats the above described procedure in response to each bit line selection signal and column group selection signal to connect each one of the sixteen bit lines BL0˜BL15 with the data line DL1. Thus, the above-described procedure causes a speed delay.

However, in the exemplary embodiment of the present invention, each of the data lines DL0˜DL3 is connected directly to the sixteen NMOS transistors 60˜90, thereby avoiding a speed delay caused by the indirectly connected NMOS transistors and a data line, and realizing a high-speed operation.

As described above, in the exemplary embodiment of the present invention, the number of lines transmitting the control signals for selecting bit lines is reduced in a local column decoder of a semiconductor memory device, therefore the layout of the semiconductor memory device is simplified and the size of a semiconductor memory device is reduced.

Further, a speed delay is reduced by directly connecting each of the NMOS transistors with a bit line and a data line, thereby increasing the speed of reading or writing data in a read or write operation in a semiconductor memory device.

While the present invention has been particularly shown and described with reference to an exemplary embodiment thereof, it will be understood by those of ordinary skill in the pertinent art that various modifications and variations in form and details can be made therein without departing from the spirit and scope of the present invention as defined by the appended claims.

What is claimed is:

1. A local column decoder, comprising:
a plurality of gate circuits each for combining a first decoding signal for selecting a bit line with a second decoding signal for selecting a column group, and outputting a switching control signal for selecting a bit line of a corresponding column group; and
a plurality of bit line selectors each for connecting the bit line of a corresponding column group among numerous column groups with a corresponding data line among numerous data lines in response to the switching control signal outputted from the plurality of gate circuits.

2. The local column decoder according to claim 1, wherein the first decoding signal and the second decoding signal are output from a global column decoder.

3. The local column decoder according to claim 1, each of the plurality of gate circuits comprising four NOR gates.

4. The local column decoder according to claim 3, said plurality of bit line selectors comprising sixteen NMOS transistors, each of which is connected to one of sixteen bit lines.

5. The local column decoder according to claim 4, wherein the plurality of bit line selectors are classified into four sub-column groups, which are sequentially coupled with a first through fourth data lines.

6. A semiconductor memory device, comprising:
a global column decoder for receiving and decoding an address output from an address buffer, and outputting a first plurality of decoding signals for selecting bit lines and a second plurality of decoding signals for selecting column groups;
a local column decoder for receiving the first plurality of decoding signals for selecting the bit lines and the second plurality of decoding signals for selecting the column groups output from the global column decoder, and decoding both the first and second plurality of decoding signals to connect a bit line of a corresponding column group with a data line.

7. The semiconductor memory device according to claim 6, the local column decoder comprising:
a plurality of data lines;
a plurality of gate circuits each for combining the first plurality of decoding signals for selecting bit lines with the plurality of second decoding signals for selecting column groups, and outputting a plurality of switching control signals for selecting a bit line of a corresponding column group; and
a plurality of bit line selectors for connecting a bit line of a corresponding column group among numerous column groups with a corresponding data line among numerous data lines in response to the switching control signal output from the plurality of gate circuits.

8. The local column decoder according to claim 7, each of the plurality of gate circuits comprising four NOR gates.

9. The local column decoder according to claim 7, each of the plurality of bit line selectors comprising sixteen NMOS transistors connected to sixteen bit lines.

10. The local column decoder according to claim 9, wherein the plurality of bit line selectors are classified into four sub-column groups, which are sequentially coupled with a first through fourth data lines.

11. The local column decoder according to claim 7, the plurality of data lines comprising four data lines.

12. A method for connecting data lines with bit lines in a read or write operation in a semiconductor memory device, comprising:
outputting a first plurality of decoding signals for selecting bit lines and a second plurality of decoding signals for selecting column groups from a global column decoder;
receiving the first plurality of decoding signals for selecting bit lines and the second plurality of decoding signals for selecting column groups in a local column decoder; and
decoding both the first and second plurality of decoding signals to connect a bit line of a corresponding column group with a data line.

13. The method of claim 12, further comprising:
combining the first plurality of decoding signals for selecting bit lines with the second plurality of decoding signals for selecting column groups in a plurality of gate circuits;
outputting a switching control signal for selecting a bit line of a corresponding column group from one of the plurality of gate circuits;
connecting the bit line of a corresponding column group among numerous column groups with a corresponding data line among numerous data lines in response to the switching control signal in a plurality of bit line selectors.

14. The method of claim 13, the plurality of bit line selectors comprising sixteen NMOS transistors.

15. The method of claim 14, further comprising:
connecting each of the sixteen transistors to a bit line among sixteen bit lines.

16. The method of claim 14, further comprising:
classifying the sixteen NMOS transistors into four sub-column groups; and
coupling the four sub-column groups sequentially with a first through fourth data lines.
